(19) United States
(12) Patent Application Publication
(10) Pub. No.: US 2025/0357085 A1
(43) Pub. Date: Nov. 20, 2025

(54) Device for Performing Plasma Treatment, and Method for Performing Plasma Treatment

(71) Applicant: Tokyo Electron Limited, Tokyo (JP)

(72) Inventor: Jianming HAO, Yamanashi (JP)

(21) Appl. No.: 19/281,310

(22) Filed: Jul. 25, 2025

Related U.S. Application Data
(63) Continuation of application No. PCT/JP2024/003135, filed on Jan. 31, 2024.

(30) Foreign Application Priority Data
Feb. 7, 2023 (JP) 2023-016969

(51) Int. Cl. H01J 37/32; C23C 16/455

(52) U.S. Cl. CPC H01J 37/32422; C23C 16/45565; H01J 37/32091; H01J 37/32449; H01J 37/32715

(57) ABSTRACT

There is provided an apparatus for performing plasma processing by supplying a processing gas in a plasma state to a substrate in a processing chamber. The apparatus comprises: a placing table configured to place the substrate thereon; a plasma generation space located above the placing table; a processing gas supply part configured to supply the processing gas to the plasma generation space; and a shower plate located between the plasma generation space and the placing table, and forming a processing space for processing the substrate between the stage and the shower plate. The shower plate includes: a first surface having a plurality of plasma inflow holes; a second surface having a plurality of plasma outflow holes; a plurality of ion trap spaces partitioned from each other by a partition wall provided between the first surface and the second surface.

### CROSS-REFERENCE TO RELATED APPLICATIONS

This application is a bypass continuation application of International Application No. PCT/JP2024/003135 having an international filing date of Jan. 31, 2024 and designating the United States, the International Application being based upon and claiming the benefit of priority from Japanese Patent Application No. 2023-016969 filed on Feb. 7, 2023, the entire contents of which are incorporated herein by reference.

### TECHNICAL FIELD

The present disclosure relates to an apparatus for performing plasma processing and a method for performing plasma processing.

### BACKGROUND

It is known that, in the manufacturing process of semiconductor devices, highly reactive active species obtained by converting a processing gas into plasma are used to perform film formation or etching on a semiconductor wafer (hereinafter, referred to as “wafer”). The active species include ions and radicals. Among them, radicals may be selectively used to perform plasma processing.

For example, Japanese Laid-open Patent Publication No. 2019-203155 discloses a technique in which a reactive gas is dissociated by capacitively coupled plasma generated between an upper electrode and a shower plate, and then supplied as remote plasma from the shower plate. Japanese Laid-open Patent Publication No. 2019-203155 also discloses a technique in which a porous plate-shaped ion trap is provided directly below the shower plate to trap ions in the plasma.

### SUMMARY

The present disclosure provides a technique for performing plasma processing on a substrate while suppressing the influence of ions contained in plasma produced from a processing gas.

In accordance with one aspect of the present disclosure, there is provided an apparatus for performing plasma processing by supplying a processing gas in a plasma state to a substrate in a processing chamber. The apparatus comprises: a placing table provided in the processing chamber and configured to place the substrate thereon; a plasma generation space located above the placing table and constituting a plasma generation mechanism configured to produce plasma from the processing gas; a processing gas supply part configured to supply the processing gas to the plasma generation space; and a shower plate located between the plasma generation space and the placing table, and forming a processing space for processing the substrate between the stage and the shower plate, wherein the shower plate includes: a first surface having a plurality of plasma inflow holes through which the plasma of the processing gas flows in from the plasma generation space; a second surface having a plurality of plasma outflow holes through which the plasma of the processing gas flows out toward the processing space; a plurality of ion trap spaces partitioned from each other by a partition wall provided between the first surface and the second surface, each of which has an ion trap surface for colliding with and trapping ions contained in the plasma of the processing gas flowing in from the plasma inflow holes, and then flowing the plasma out toward the processing space through the plasma outflow holes.

### BRIEF DESCRIPTION OF THE DRAWINGS

FIG. 1 is a longitudinal side view of a film forming apparatus according to an embodiment of the present disclosure.

FIG. 2 is a longitudinal side view showing a configuration example of a shower plate and a plasma generation space of the film forming apparatus.

FIG. 3 is a perspective view showing a first configuration example of the shower plate.

FIG. 4 is a perspective view of the shower plate according to the first configuration example, which is seen from another direction.

FIG. 5 is a perspective view showing a second configuration example of the shower plate.

FIG. 6 is a perspective view of the shower plate according to the second configuration example, which is seen from another direction.

FIG. 7 is an operation diagram of an example of an ion trap space provided in the shower plate.

FIG. 8 is a longitudinal side view showing a third configuration example of the shower plate.

FIG. 9 is an operation diagram illustrating an example of an ion trap space in which a conductive member supplied with power is provided in a partition wall.

FIG. 10 is a longitudinal side view of an example of a shower plate in which a communication passage interconnecting ion trap spaces is provided in a partition wall.

FIG. 11 is an enlarged longitudinal perspective view of an example of a shower plate provided with a plasma outflow hole having a gradually expanding n opening area.

FIG. 12 is a longitudinal side view of a shower plate in which an ion trap surface is formed as a tapered surface.

FIG. 13 shows a simulation model of the shower plate.

FIG. 14 is a graph showing simulation results.

### DETAILED DESCRIPTION

### <Film Forming Apparatus 1>

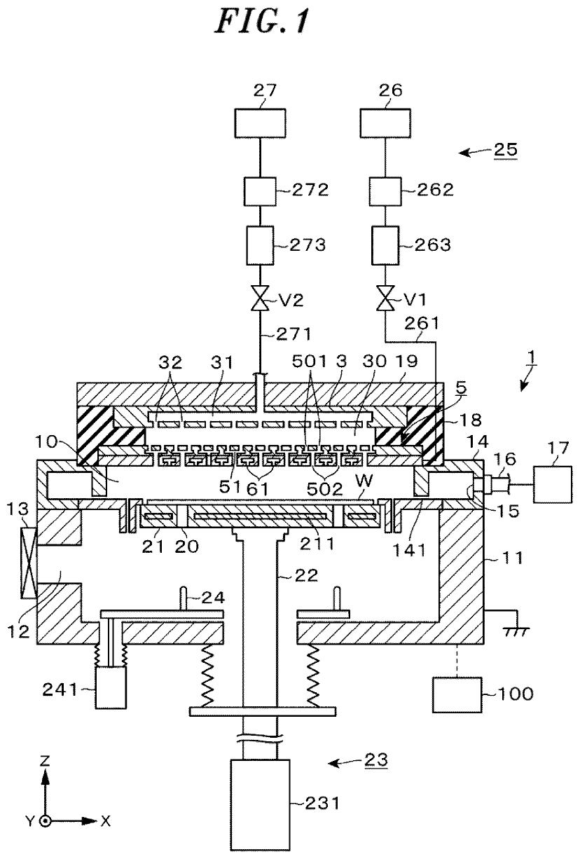

First, an example of an overall configuration of a film forming apparatus 1, which is one embodiment of “apparatus for performing plasma processing” according to the present disclosure, will be described with reference to FIG. 1. The film forming apparatus 1 of this example is configured to supply a reactive gas (processing gas) in a plasma state and a raw material gas containing a film raw material to a wafer, and form a film of a desired material on the surface of the wafer. A film to be formed on the wafer is not particularly limited, and the film may be a metal oxide film or a metal nitride film for forming an insulating film, or a metal film. In addition, as will be described later, the film forming apparatus 1 has a configuration capable of suppressing the influence of ions contained in active species at the time of supplying a reactive gas in a plasma state to the wafer.

The film forming method performed by the film forming apparatus 1 may be a CVD method in which a raw material gas and a reactive gas in a plasma state are continuously supplied and a film material is deposited on the surface of the wafer. Alternatively, it is possible to use an ALD method in which the supply and exhaust of the raw material gas and the supply and exhaust of the reactive gas in a plasma state are alternately performed to repeat the adsorption of the raw material gas on the wafer and the reaction of the reactive gas, thereby depositing a thin film of the film material.

A processing chamber 11 in this example is made of a flat cylindrical metal, and is grounded. The sidewall of the processing chamber 11 is provided with a loading/unloading port 12 for loading/unloading the wafer W, and a gate valve 13 for opening/closing the loading/unloading port 12. An exhaust duct 14 having a circular ring shape in plan view is provided above the loading/unloading port 12. A slit-shaped exhaust port 141 extending in the circumferential direction is formed on the inner circumferential surface of the exhaust duct 14. An opening 15 is formed on the sidewall surface of the exhaust duct 14, and an exhaust mechanism 17 including a pressure control mechanism and a vacuum pump is connected to the opening 15 through an exhaust line 16.

A placing table 21 for placing the wafer W horizontally is provided in the processing chamber 11. A heater 211 for heating the wafer W is embedded in the placing table 21. An upper end of a rod-shaped support member 22 that penetrates through a bottom portion of the processing chamber 11 and extends in the vertical direction is connected to the central portion of the bottom surface of the placing table 21, and a driving part 231 is connected to the lower end of the support member 22. The support member 22 and the driving part 231 constitute a lifting mechanism 23 for the placing table 21. The lifting mechanism 23 allows the placing table 21 to move up and down between an upper position serving as a processing position shown in FIG. 1 and a lower position under the processing position. The lower position serves as a transfer position for transferring the wafer W to and from a transfer mechanism (not shown) for the wafer W that enters the processing chamber 11 from the loading/unloading port 12. At the processing position, the space above the placing table 21 constitutes a processing space 10 for processing the wafer W.

In addition, a plurality of support pins 24, which can be raised and lowered by the lifting mechanism 241, are arranged below the placing table 21. When the placing table 21 is located at the transfer position, the support pins 24 are raised and lowered to protrude from and retract below the upper surface of the placing table 21 through through-holes 20 formed in the placing table 21. Due to the above operation, the wafer W can be transferred between the placing table 21 and the transfer mechanism.

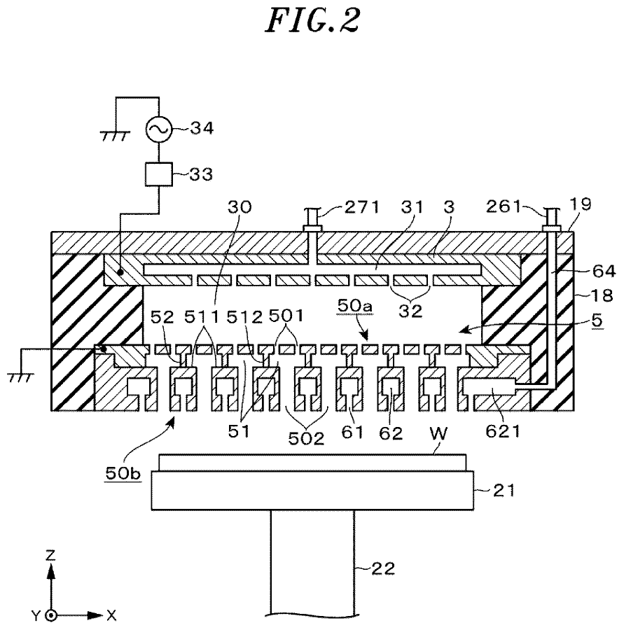

A plasma generation space 30 for converting the reactive gas that is the processing gas into plasma, and a shower plate 5 having therein a plurality of ion trap spaces 51 to be described later are arranged inside the exhaust duct 14 formed in a circular ring shape, i.e., above the placing table 21. The detailed configurations of the plasma generation space 30 and the shower plate 5 will be described in FIG. 2 and subsequent drawings, so that the configuration example of a gas supply system 25 for supplying various gases to these spaces will be described first.

### <Gas Supply System 25>

The gas supply system 25 in this example includes a raw material gas supply source 26 that supplies a raw material gas, and a reactive gas supply source 27 that supplies a reactive gas. The raw material gas is a gas containing a precursor (film raw material) that is a raw material of a film material of a film to be formed on the wafer W. The reactive gas is a gas that reacts with the precursor to obtain the film material.

In the case of forming a film containing a metal, such as titanium, a raw material gas containing titanium tetrachloride (TiCl₄) may be used as the film material. The reactive gas may be oxygen (O₂) gas or ozone (03) gas in the case of forming an oxide film, ammonia (NH₃) gas in the case of forming a nitride film, and hydrogen (H₂) gas that is a reducing gas in the case of reducing a precursor to form a metal film. An auxiliary gas such as argon (Ar) gas may be added to the reactive gas to assist in converting the reactive gas into plasma. A purge gas may be an inert gas such as nitrogen (N₂) gas, Ar gas, helium (He) gas, krypton (Kr) gas, neon (Ne) gas, and xenon (Xe) gas, or a processing gas that is not converted into plasma.

One end of a raw material gas supply line 261 is connected to the raw material gas supply source 26, and a flow rate controller 262 and a valve V1 are provided in the raw material gas supply line 261 from the upstream side. One end of a reactive gas supply line 271 is connected to the reactive gas supply source 27, and a flow rate controller 272 and a valve V2 are provided in the reactive gas supply line 271 from the upstream side. Further, in the case of forming a film by ALD, storage tanks 263 and 273 for respective gases may be provided on the upstream sides of the valves V1 and V2 in order to supply a sufficient amount of the raw material gas and the reactive gas in a short time of time.

Further, the configuration of the gas supply system 25 is not limited to this example. For example, a purge gas supply line for supplying a purge gas that facilitates the discharge of the raw material gas or the reactive gas from the processing chamber 11 may join the gas supply lines 261 and 271.

### <Plasma Generation Space 30>

Hereinafter, the configuration of the plasma generation space 30 and the shower plate 5 will be described with reference to FIGS. 2 to 6. Since FIG. 1 explains the overall configuration of the film forming apparatus 1, the configuration of the shower plate 5 is illustrated in a simplified manner.

First, the configuration example in the plasma generation space 30 will be described. The plasma generation space 30 constitutes a plasma generation mechanism for converting a reactive gas into plasma. In this example, the plasma generation space 30 is formed between the shower head 3 for supplying a reactive gas and the shower plate 5, which are arranged to face each other horizontally, with a circular ring-shaped sidewall portion 18 made of a dielectric material interposed therebetween.

In this example, the shower head 3 is located at the ceiling portion of the processing chamber 11 as shown in FIGS. 1 and 2, and is formed in a circular shape with a diameter greater than that of the wafer W in plan view. A gas diffusion space 31 is formed in the shower head 3, and a plurality of injection holes 32 penetrating through the components thereof in the thickness direction and communicating with the diffusion space 31 are formed in a distributed manner on the bottom surface of the shower head 3.

The shower head 3 is made of a metal, and the bottom surface thereof functions as an upper electrode for generating capacitively coupled plasma (CCP). From this perspective, the shower head 3 corresponds to the electrode plate of the present embodiment. As shown in FIG. 2, the components of the shower plate 5 are grounded.

As shown in FIG. 2, the shower head 3 is connected to an AC high-frequency power supply part 34 via a matching device 33, and is configured to supply a high-frequency power. The frequency of the high-frequency power supply part 34 may be 13.56 MHz or 2.45 GHZ, for example. In this case, DC may be superimposed onto the high-frequency power. Further, instead of the AC high-frequency power supply part 34, a DC power supply may be used to apply a DC pulse by pulse width modulation (PWM). Further, instead of the above example, a configuration in which the shower head 3 is grounded and the high-frequency power supply part 34 is connected to the shower plate 5 may be considered.

The reactive gas is supplied to the plasma generation space 30 from the reactive gas supply line 271 via the shower head 3. From this perspective, the reactive gas supply line 271 and the reactive gas supply source 27 connected to the upstream side thereof, the flow rate controller 272, and the like constitute the processing gas supply part of this example.

### <Shower Plate 5>

Next, the configuration example of the shower plate 5 will be described with reference to FIGS. 2 to 6. FIG. 2 is an enlarged view of the shower plate 5 in the vertical direction (Z direction). The shower plate 5 is provided between the plasma generation space 30 and the processing space 10, and is located to face the wafer W placed on the placing table 21.

For example, the shower plate 5 is formed in a disc shape with a diameter greater than that of the wafer W, and the peripheral region thereof is located on the bottom surface side of the sidewall portion 18 described above. The bottom peripheral edge of the shower plate 5 in this example is supported by the exhaust duct 14, and the sidewall portion 18 is provided to connect the upper surface of the exhaust duct 14 and the ceiling portion 19 of the processing chamber 11.

Accordingly, the inside of the film forming apparatus 1 is divided into upper and lower parts by the shower plate 5, and the upper part of the shower plate 5 is configured as the plasma generation space 30, and the lower part thereof is configured as the processing space 10. Hereinafter, the upper surface of the shower plate 5 located to face the plasma generation space 30 is also referred to as “first surface 50a” and the bottom surface of the shower plate 5 located to face the processing space 10 is also referred to as “second surface 50b.”

The plurality of ion trap spaces 51 are provided inside the shower plate 5. The ion trap spaces 51 are partitioned from each other by partition walls 512 provided between the first surface 50a and the second surface 50b. The ion trap spaces 51 communicate with a plurality of plasma inflow holes 501 formed on the first surface 50a, and the plasma of the reactive gas formed in the plasma generation space 30 flows into the ion trap spaces 51 through the plasma inflow holes 501. Further, the ion trap spaces 51 communicate with a plurality of plasma outflow holes 502 formed on the second surface 50b, and the plasma of the reactive gas that flows into the ion trap spaces 51 flows out toward the processing space 10 through the plasma outflow holes 502.

In this manner, the reactive gas in a plasma state in the plasma generation space 30 flows through the plurality of ion trap spaces 51 formed in the shower plate 5, and then is supplied to the processing space 10. From this perspective, the film forming apparatus 1 of this example constitutes a remote-type plasma processing apparatus.

Here, the highly reactive active species obtained by converting the reactive gas into plasma include ions, radicals, and neutral particles. Among the ions, high-energy ions may cause electrical damage to a film to be formed on the wafer or a base material, or may cause physical damage from collision due to high-speed movement. Further, the high-energy ions may cause excessive dissociation of the film raw material, which makes it difficult to control the film formation. Therefore, it is preferable to perform processing by supplying ions, radicals, and neutral particles having energy suitable for film formation to the wafer W while suppressing the influence of high-energy ions, which are contained in the reactive gas in a plasma state.

### <Ion Trap Space 51>

In this example, an ion trap surface 511 for trapping ions contained in the plasma by causing collision of the ions is provided in each ion trap space 51, thereby reducing the content of ions contained in the active species. The ion trap space 51 is configured to allow selective passage of radicals and neutral particles in the plasma and supply them to the wafer W.

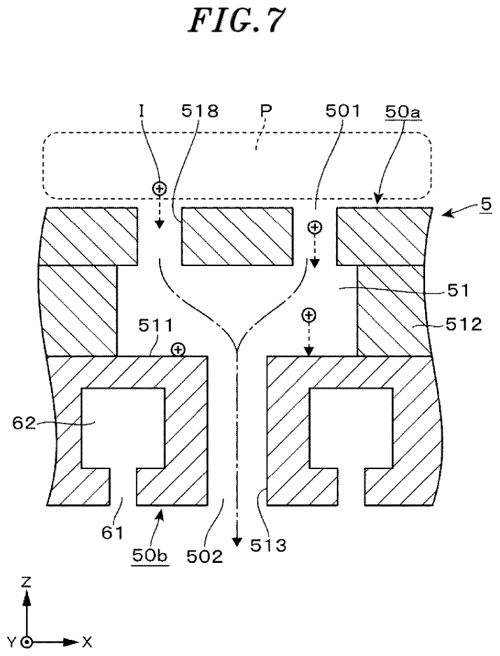

As shown in FIGS. 2 and 7, in the ion trap space 51 of this example, the opening area of the plasma outflow hole 502 is set to be smaller than the horizontal cross-sectional area of the ion trap space 51 in which the plasma outflow hole 502 is provided. In achieving this setting, the component of the lower region of the shower plate 5 that forms the plasma outflow hole 502 has a component that protrudes toward the inner side of the ion trap space 51 from the inner wall surface of the partition wall 512 that partitions the ion trap space 51. The upper surface of the component (hereinafter, also referred to as “protruding part 513”) that protrudes inward from the inner wall surface of the partition wall 512 is located at a position facing the outlet side opening of the plasma inflow hole 501. In this configuration, the upper surface of the protruding part 513 corresponds to the ion trap surface 511 of this example.

The configuration and arrangement of the plurality of ion trap spaces 51 in the shower plate 5 can be variously changed.

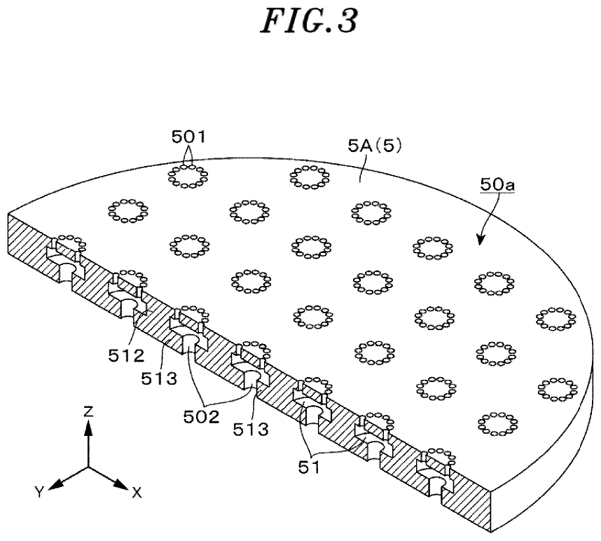

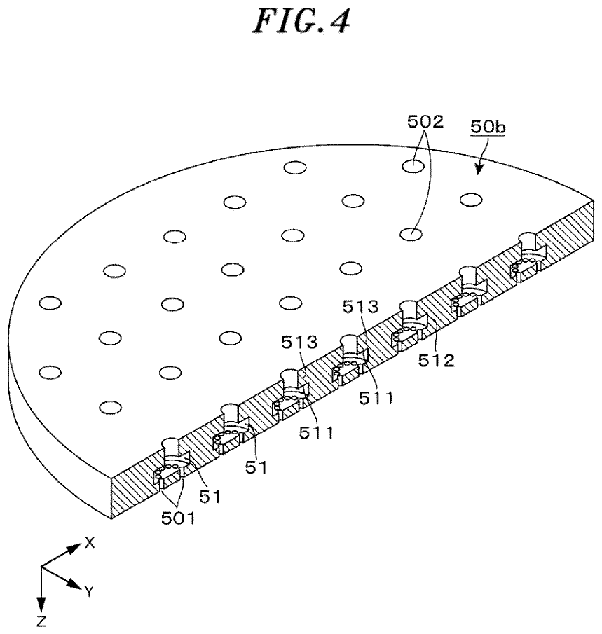

For example, in a shower plate 5A shown in the partially exploded perspective views of FIGS. 3 and 4, each ion trap space 51 is formed in a cylindrical shape. Further, the cylindrical ion trap spaces 51 are arranged in a matrix shape in the surface of the shower plate 5A. In the present disclosure, as shown in FIGS. 3 and 4, and FIG. 11 to be described later, the concept of “cylindrical” also includes the flat and disc-shaped ion trap spaces 51 having a diameter greater than a height in the vertical direction.

Here, FIG. 3 shows the shower plate 5A viewed from the first surface 50a, and FIG. 4 shows the shower plate 5A viewed from the second surface 50b. The plasma inflow holes 501 provided to correspond to the ion trap spaces 51 are arranged in a ring shape along the cross-sectional shape of the cylindrical ion trap spaces 51. The sets of the plasma inflow holes 501 arranged in a ring shape are arranged in a matrix (see FIG. 3).

The ion trap surfaces 511 are also formed in a small ring shape along the inner wall surfaces of the cylindrical partition walls 512 to correspond to the arrangement of the plasma inflow holes 501. The plasma outflow holes 502 are formed as small hole-shaped channels provided inside the annular ion trap surfaces 511 (see FIG. 4). Further, in FIGS. 3 and 4, the illustration of a diffusion space 62 and a raw material gas supply hole 61, which will be described later, is omitted.

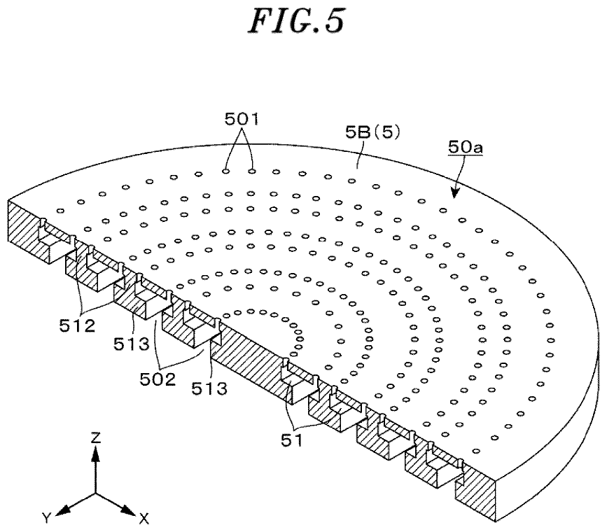

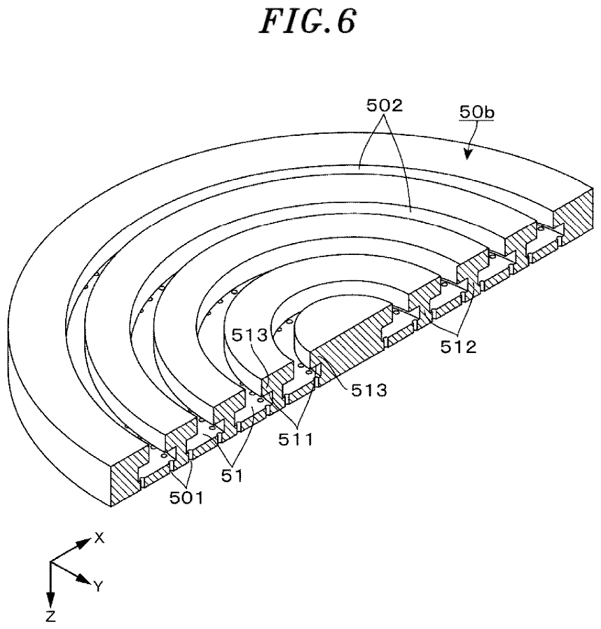

On the other hand, in a shower plate 5B shown in the partially exploded perspective views of FIGS. 5 and 6, the ion trap spaces 51 are formed in an annular shape along the circumferential direction of the shower plate 5B. Further, the plurality of annular ion trap spaces 51 are arranged concentrically in the surface of the shower plate 5B.

FIG. 5 shows the shower plate 5B viewed from the first surface 50a side, and FIG. 6 shows the shower plate 5B viewed from the second surface 50b side. The plasma inflow holes 501 provided to correspond to the ion trap spaces 51 are arranged in an annular shape along the planar shape of the ring-shaped ion trap spaces 51. Further, the sets of the plasma inflow holes 501 arranged in an annular shape are arranged concentrically (see FIG. 5).

The ion trap surface 511 is also formed in an annular shape along both the inner wall surfaces on the inner circumferential side and the outer circumferential side of the annular partition wall 512 to correspond to the arrangement of the plasma inflow hole 501. In other words, two annular ion trap surfaces 511 are arranged in the ion trap space 51 of the shower plate 5B. The plasma outflow hole 502 is formed as an annular slit channel to be sandwiched between the two annular ion trap surfaces 511 (see FIG. 6). In FIGS. 5 and 6, the illustration of the diffusion space 62 and the raw material gas supply hole 61, which will be described later, is omitted, similarly to FIGS. 3 and 4.

### <Raw Material Gas Supply Hole 61>

Further, in addition to the above-described ion trap spaces 51 for supplying a reactive gas in a plasma state, a plurality of raw material gas supply holes 61 for supplying a raw material gas toward the processing space 10 is formed at the shower plate 5. In the example shown in FIGS. 1, 2, and 7, the raw material gas diffusion space 62 and the raw material gas supply hole 61 communicating with the diffusion space 62 are provided in a region different from the region where the plasma outflow holes 502 are formed at the bottom of the ion trap space 51.

Although not shown as described above, for example, the plurality of raw material gas diffusion spaces 62 may be formed in a cylindrical shape (including “disc shape” as described above) and arranged in a matrix shape, similarly to the ion trap spaces 51 shown in FIGS. 3 and 4. The diffusion spaces 62 may also be formed in an annular shape and arranged concentrically, similarly to the ion trap spaces 51 shown in FIGS. 4 and 5.

The plurality of diffusion spaces 62 are connected to each other by a gas channel (not shown). The plasma outflow holes 502 are formed to penetrate through the space between the diffusion spaces 62. Further, the raw material gas supply holes 61 are formed at the bottom portions of the diffusion spaces 62. As described above, the plasma outflow holes 502 through which the reactive gas flows after the ions are trapped are arranged in a matrix shape or concentrically. In this case, the raw material gas supply holes 61 are formed in a small hole shape or a slit shape to be located between the plasma outflow holes 502.

Further, as shown in FIG. 2, a downstream end of a raw material gas supply line 64 is connected to a diffusion space 621 formed on the peripheral side of the shower plate 5. The raw material gas supply line 64 is formed to extend vertically in the sidewall portion 18 and opened to the ceiling portion 19 of the processing chamber 11, as shown in FIG. 2, for example. The upstream side of the raw material gas supply line 64 is connected to the raw material gas supply line 261 of the gas supply system 25. Accordingly, the raw material gas supplied from the raw material gas supply line 261 to the raw material gas supply line 64 is supplied to the diffusion spaces 62 through the interconnecting diffusion spaces, and is discharged from the raw material gas supply holes 61 toward the processing space 10.

The shower plate 5 configured as described above may include a single member, or may be formed by combining a plurality of members. The shower plate 5 is made of, for example, a metal such as stainless steel or aluminum, or a dielectric material such as quartz, ceramics, or resin. In particular, when capacitively coupled plasma is generated between the shower head 3 and the shower plate 5 as described above, for example, the member constituting the first surface 50a is made of a metal. The surface of the metallic member of the shower plate 5 that constitutes the first surface 50a may be covered with a conductive film or a dielectric film.

Referring back to the description of FIG. 1, the film forming apparatus 1 includes a controller 100. The controller 100 includes a computer including a storage part storing a program, a memory, and a CPU. The program includes commands (steps) for outputting control signals from the controller 100 to individual components of the film forming apparatus 1 and for performing loading/unloading of the wafer W and film formation. The programs are stored in the storage part of the computer, such as a flexible disk, a compact disk, a hard disk, a magneto-optical (MO) disk, a non-volatile memory, or the like, and are read from the storage part and installed in the controller 100.

### <Film Formation>

Next, the operation of performing film formation as plasma processing on the wafer W using the film forming apparatus 1 having the above-described configuration will be described.

When a wafer W to be processed is transferred to an external vacuum transfer chamber, the gate valve 13 is opened, and a transfer mechanism (not shown) holding the wafer W enters the processing chamber 11 through the loading/unloading port 12. Then, the wafer W is transferred to the placing table 21 standing by at the lower position using the support pins 24.

Then, the transfer mechanism retracts from the processing chamber 11. The gate valve 13 is closed, and the pressure in the processing chamber 11 and the temperature of the wafer W are adjusted. Next, the reactive gas is supplied to the plasma generation space 30 (step of supplying a processing gas), and a high-frequency power is applied from the high-frequency power supply part 34 to the shower head 3.

By applying the high-frequency power to the shower head 3, capacitively coupled plasma is generated between the shower head 3 and the shower plate 5, and the reactive gas supplied to the plasma generation space 30 is converted into plasma (step of converting a processing gas into plasma). As described above, an auxiliary gas such as Ar gas or the like may be supplied simultaneously to the reactive gas to be converted into plasma.

### <Action of Ion Trap Space 51>

The reactive gas in a plasma state in the plasma generation space 30 flows into the ion trap spaces 51 through the plasma inflow holes 501 (step of causing plasma to flow into the ion trap spaces). In this case, as shown in FIG. 7, the ion trap spaces 51 are provided at positions facing the outlet openings of the plasma inflow holes 501. The plasma of the reactive gas that has entered the ion trap spaces 51 flows toward the ion trap surfaces 511 along the injection direction from the plasma inflow holes 501. Then, the flow direction of the plasma is changed while being guided by the ion trap surfaces 511, and the plasma flows into the plasma outflow holes 502.

The plasma of the reactive gas contains active species such as ions I and radicals, and neutral particles. A sheath region with a potential lower than that of the region of the bulk flow of the plasma is formed near the surface of the sidewall 518 of the plasma inflow holes 501. Therefore, some of the ions I with positive charges are attracted to the sheath region near the surface of the sidewall 518, and are trapped on the surface of the sidewall 518. Then, the ions I traveling linearly collide with the ion trap surfaces 511 and are trapped on the surfaces of the ion trap surfaces 511 (step of trapping ions).

Due to the above-described action, the high-energy ions I contained in the plasma of the reactive gas are efficiently trapped. As a result, remote plasma with a low ion content and a high radical content can be supplied to the wafer W on the placing table 21 through the plasma outflow holes 502 (step of causing plasma to flow into the processing space).

Here, in the shower plate 5 of this example, the plurality of ion trap spaces 51 are partitioned from each other by the partition walls 512. In other words, the shower plate 5 has a configuration in which the member constituting the first surface 50a located toward the plasma generation space 30 and the member constituting the second surface 50b located toward the processing space 10 are connected by the plurality of partition walls 512.

Heat is incident from the plasma on the first surface 50a located toward the plasma generation space 30. Here, there is considered a case where heat is incident from the plasma on the shower plate in a conventional film forming apparatus in which a porous plate-shaped ion trap is located directly below a porous plate-shaped shower plate as in the technique disclosed in Japanese Laid-open Patent Publication No. 2019-203155, which is described in Background Art. In the case of the conventional configuration, the heat transferred from the plasma to the shower plate is transferred only to the peripheral part of the shower plate to be in contact with other members. Hence, it is difficult to uniformly cool the entire shower plate, and a region where a large temperature difference occurs between the center and the periphery may be generated, for example.

When a large temperature difference occurs in the surface of the shower plate, the plasma state of the reactive gas in the plasma generation space 30 becomes considerably non-uniform in the surface, and a difference in concentration such as concertation of active species or the like may occur. As a result, plasma with a large difference in the concentration distribution of active species between the center and the periphery is supplied to the wafer W located to face the shower plate, which may impair the film formation with high in-surface uniformity.

As described above, in the shower plate 5 of the present embodiment, the member constituting the first surface 50a and the member constituting the second surface 50b are connected by the plurality of partition walls 512. This corresponds to the conventional configuration in which the porous plate-shaped shower plate and the porous plate-shaped ion trap located directly therebelow are connected by the plurality of partition walls 512. Therefore, the plurality of partition walls 512 serve as heat transfer paths, and heat can be dissipated from the component on the first surface 50a side, where heat is incident from the plasma, through the component on the second surface 50b side, where heat is not incident from the plasma. As a result, it is possible to generate plasma with more uniform distribution of concentration of active species in the first surface 50a, thereby performing film formation with high in-surface uniformity.

Further, by providing the plurality of ion trap spaces 51 partitioned by the partition walls 512, the shape (cylindrical shape, annular shape, polyhedral shape, or the like) of the ion trap spaces 51 and the arrangement (matrix arrangement or concentric arrangement) of the plurality of ion trap spaces 51 can be set variously (see FIGS. 3, 4, 5, and 6). In addition, in each ion trap space 51, it is possible to set many design variables, such as the height, width, and arrangement angle of the ion trap space 51, the ratio of the horizontal cross-sectional area of the ion trap space 51 to the opening area of the plasma outflow hole 502, the width and area of the ion trap surface 511, and the formation of the ion trap surface 511 as a tapered surface. By optimizing the design variables, it is easy to perform optimal design for searching for a configuration in which the ions I are trapped more efficiently.

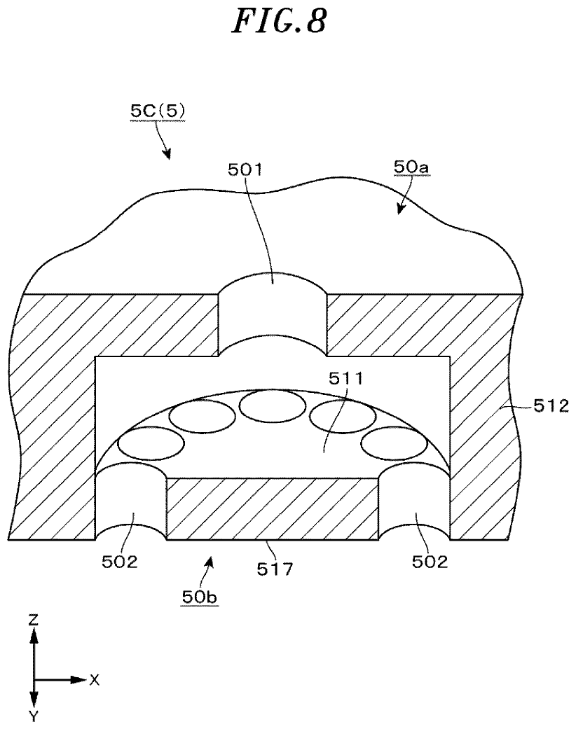

Here, as in the ion trap space 51 illustrated in FIGS. 3 to 7, it is not necessary to provide the plurality of plasma inflow holes 501 on the first surface 50a side and one plasma outflow hole 502 on the second surface 50b side in each ion trap space 51. For example, in a shower plate 5C shown in FIG. 8, a bottom plate portion 517 is located on the bottom surface side of each ion trap space 51. Further, on the first surface 50a side, one plasma inflow hole 501 is provided to face the central region of the upper surface of the bottom plate portion 517. A plurality of plasma outflow holes 502 are provided on the peripheral portion of the bottom plate portion 517 surrounding the central region. In this configuration, the central region of the upper surface of the bottom plate portion 517 that faces the outlet of the plasma inflow hole 501 constitutes the ion trap surface 511.

In the above-described film formation, in the case of forming a film by a CVD method, the supply of the reactive gas in a plasma state after the ions I are trapped in the ion trap spaces 51 and the supply of the raw material gas through the raw material gas supply holes 61 may be performed at the same time.

Further, in the case of forming a film by an ALD method, for example, a cycle of “supply of the raw material gas through the raw material gas supply holes 61 (adsorption of precursor to the wafer W)→supply of the purge gas through the ion trap spaces 51 and the raw material gas supply holes 61→supply of the reactive gas in a plasma state through the ion trap spaces 51 (reaction with the precursor adsorbed to the wafer W)→supply of the purge gas through the ion trap spaces 51 and the raw material gas supply holes 61” is repeated a predetermined number of times.

After a film is formed by the CVD method or the ALD method for a preset period, the supply of the reactive gas, the supply of the raw material gas, and the supply of high-frequency power to the shower head 3 are stopped. Then, the wafer W on which the film is formed is unloaded from the processing chamber 11 in the reverse order of the loading process.

### <Effects>

The film forming apparatus 1 according to the present embodiment has the following effects. The reactive gas in a plasma state is introduced into the plurality of ion trap spaces 51 so that the ions I are trapped on the ion trap surfaces 511, and then is supplied to the processing space 10 through the plasma outflow holes 502. As a result, the reactive gas with an increased concentration of radicals can be supplied to the wafer W, thereby performing film formation.

### Second Embodiment

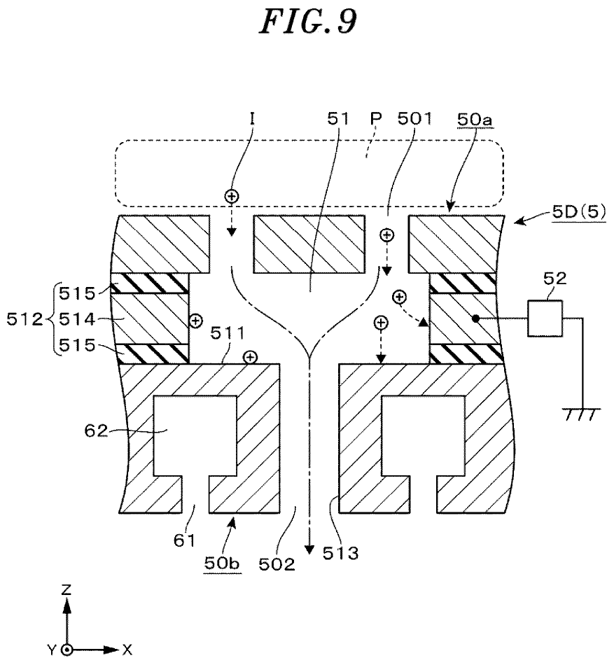

FIG. 9 shows a second embodiment in which the ions I can be trapped on the inner wall surfaces of the partition walls 512 as well as the ion trap surfaces 511. In FIGS. 9 to 13, like reference numerals are used for like parts as those described in FIGS. 1 to 7.

As shown in FIG. 9, in a shower plate 5D according to the second embodiment, the partition wall 512 has layers of insulating members 515 arranged to be in contact with the metallic members constituting the first surface 50a and the second surface 50b. Further, a layer of conductive member 514 is provided to be sandwiched between the insulating members 515, and the power supply part 52 is connected to the conductive member 514. Here, the power supply part 52 may be configured as a DC power supply, and the negative pole may be connected to the conductive member 514, for example. However, it is not necessary to connect the negative pole of the DC power supply to the conductive member 514. For example, the positive pole of the DC power supply may be connected to the conductive member 514, or the power supply part 52 may be configured as an AC power supply.

In the shower plate 5D configured as described above, when the power is applied from the power supply part 52 to the conductive member 514, the potential of the inner wall surface of the partition wall 512 that is formed by the conductive member 514 changes. As a result, the ions I can be electrically attracted to the conductive member 514 in addition to the ion trap surfaces 511 described above, and can be trapped on the inner wall surface of the conductive member 514.

### Third Embodiment

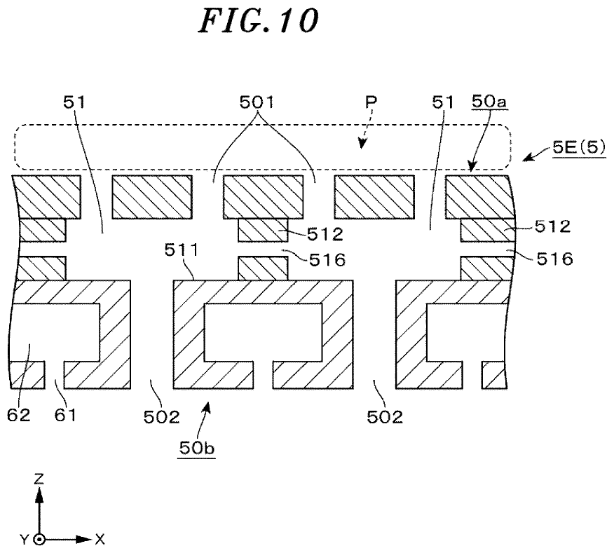

In a shower plate 5E according to a third embodiment shown in FIG. 10, a communication passage 516 for communicating the ion trap spaces 51 is provided for the partition wall 512 for partitioning the ion trap spaces 51 adjacent to each other. By providing the communication passage 516, the pressure difference between the ion trap spaces 51 adjacent to each other is reduced, and the reactive gas in a plasma state can be more uniformly supplied from the plasma outflow holes 502. In addition, the gas replacement in the ion trap spaces 51 is improved, thereby performing purging in a shorter period of time.

### Fourth Embodiment

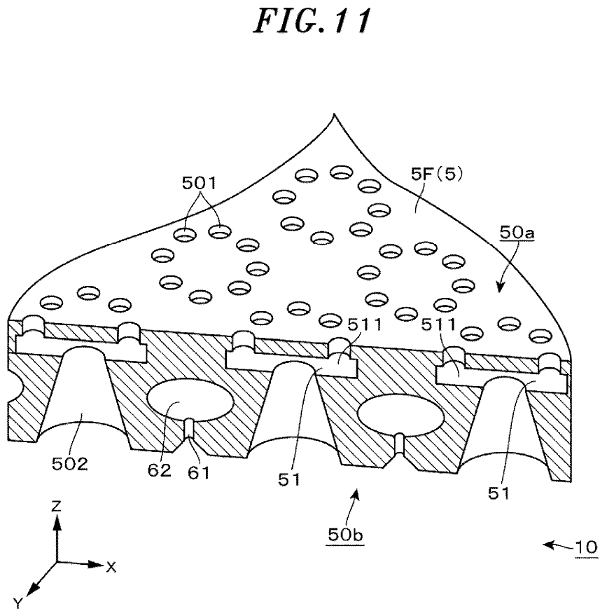

In a shower plate 5F according to a fourth embodiment shown in FIG. 11, the opening area of each plasma outflow hole 502 is gradually increased from the ion trap space 51 side toward the processing space 10 side. Since the opening area of the plasma outflow hole 502 is gradually increased, the reactive gas in a plasma state can be more uniformly supplied over a wide area in the surface of the wafer W.

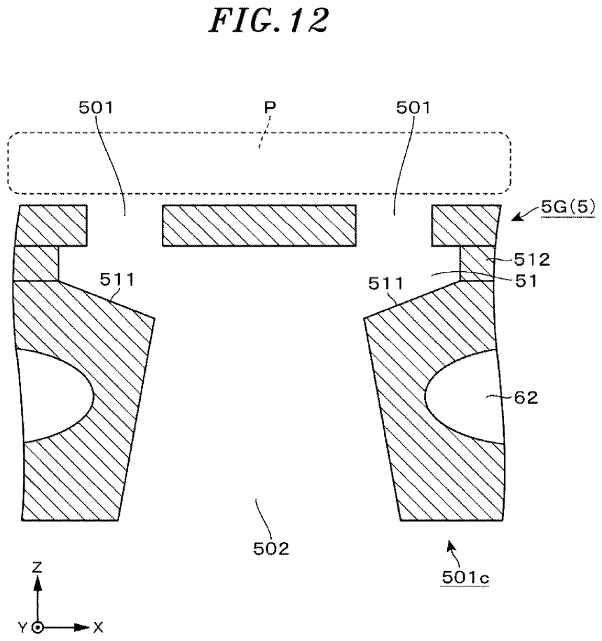

As shown in FIG. 12, the ion trap surface 511 may be formed as a tapered surface in which the height position gradually decreases from the partition wall 512 side toward the plasma outflow hole 502 side. The configuration in which the ion trap surface 511 is formed as a tapered surface may also be applied to the ion trap spaces 51 provided in the shower plates 5 and 5A to 5E according to other embodiments described with reference to FIGS. 3 to 10.

Here, the plasma generation mechanism of the film forming apparatus 1 according to each of the above-described embodiments does not necessarily have a parallel plate type configuration, and may generate plasma by microwaves. Further, inductively coupled plasma (ICP) for producing plasma from the processing gas by generating eddy currents by high-frequency varying magnetic field generated around an antenna may be used. In addition, plasma may be surface-wave plasma (SWP), discharge produced plasma (DPP), hollow cathode plasma (HCP), or the like.

Further, in the film formation performed by the apparatus shown in FIG. 1, the raw material gas supplied from the raw material gas supply hole 61 of the shower plate 5 may be SiH₄ gas, gas containing Si, NH₃ gas, gas containing N, and a metal material gas, other than TiCl₄ gas described above. Further, the raw material gas supply holes 61 are not necessarily formed at the shower plate 5, and the raw material gas may be supplied to the processing space 10 from raw material gas supply holes formed separately from the shower plate 5. For example, a raw material gas nozzle may be provided to be inserted into the processing space 10, and the raw material gas may be supplied through a raw material gas supply hole formed at the raw material gas nozzle.

The present disclosure is not limited to film formation, and may be applied to an etching apparatus for etching a film formed on a wafer W, or a modification apparatus for performing modification that modifies a substance on a wafer W by using a modification gas in a plasma state.

For example, the apparatus shown in FIG. 1 is applied to an etching apparatus, and an atomic layer etching process is performed as the etching process on a gallium arsenide film (GaAs film) formed on the surface of the wafer W. In this etching, an etchant gas is supplied to the processing space 10 through the raw material gas supply holes 61 of the shower plate 5, and is adsorbed on the GaAs film formed on the wafer surface on the placing table 21. The etchant gas may be a corrosive gas such as chlorine (Cl₂) gas or hydrogen chloride (HCl) gas.

Next, in the plasma generation space 30, an inert gas, for example, Ar gas, is converted into plasma, and supplied to the processing space 10 through the ion trap spaces 51 of the shower plate 5. In this example, the Ar gas in a plasma state in the plasma generation space 30 corresponds to the processing gas. In this case, high-energy ions are removed from Ar gas on the ion trap surfaces 511 provided in the ion trap spaces 51, and low-energy ions or radicals are supplied to the processing space 10. The radicals or low-energy ions contained in the active species of Ar gas collide with the etchant gas adsorbed on the GaAs film on the wafer surface, thereby imparting electrical energy and inducing chemical reaction between the etchant gas and the atomic layer to be etched. Accordingly, the etchant gas, the atomic layer of the GaAs film, and the inert gas are removed from the wafer surface.

Between the adsorption of the etchant gas and the supply of the Ar gas in a plasma state, a purge gas is introduced into the processing space 10 to exhaust the gas. These steps are repeated to perform a preset amount of etching.

The Ar gas in a plasma state contains ions of various energies. However, in the atomic layer etching, it is required to use low-energy ions or radicals in order to perform the etching on an atomic layer basis. In the above example, it is preferable to supply ions and radicals of Ar gas with an energy of 20 eV or less, for example, to the wafer W.

Since the etching process is performed using radicals or low-energy ions, one atomic layer of the GaAs film can be etched without damaging the wafer W or the deposited film. Therefore, even in atomic layer etching, the high-energy ions can be removed from the processing gas in a plasma state in the ion trap spaces 51.

Further, the atomic layer etching and the film formation may be performed consecutively by switching gases using the apparatus shown in FIG. 1.

Further, in the case of performing the atomic layer etching, the etchant gas supplied from the raw material gas supply holes 61 of the shower plate 5 may be CHF₃ gas, CH₃F gas, H₂ gas, BCl₃ gas, SiCl₄ gas, Br₂ gas, HBr gas, NF₃ gas, CF₄ gas, SF₆ gas, O₂ gas, SO₂ gas, or COS gas, other than Cl₂ gas and HCl gas described above.

Further, the embodiments of the present disclosure are illustrative in all respects and are not restrictive. The above-described embodiments may be omitted, replaced, or changed in various forms without departing from the scope of the appended claims and the gist thereof.

### Examples

### (Simulation)

The designs of the plasma inflow holes 501, the ion trap spaces 51, and the plasma outflow holes 502 were variously changed, and the radical concentration distribution in these regions was simulated under specific conditions (pressure, temperature, flow rate, and the like) using a fluid simulator to search for a configuration example with a small amount of radical deactivation.

### A. Simulation Conditions

A simulation model corresponding to the plasma inflow holes 501, the ion trap spaces 51, and the plasma outflow holes 502 of the configuration described with reference to FIGS. 3 and 4 was created (see FIG. 13). The diameter d1 of the plasma inflow holes 501 was set to 2 mm, the number of installations was 10, and the diameter d2 of the plasma outflow holes 502 was set to 6 mm. Further, the thickness t1 of the upper surface member of the ion trap space 51 was set to 2 mm, and the thickness t2 of the lower surface member was set to 6 mm. Under the conditions set by variously changing the diameter d3 of the ion trap space 51, the height t3 of the ion trap space 51 was determined based on the following concept. In FIG. 13, the trajectory of the ions I incident from the position of the outer periphery of the plasma inflow hole 501 is indicated by a thick arrow ID. Under these conditions, the height t3 of the ion trap space 51 was determined such that the ions I incident from the position of the outer periphery of the plasma inflow hole 501 at an incidence angle greater than or equal to the arrow ID were trapped on the surface of the ion trap surface 511 or the inner wall surface of the partition wall 512. In this case, the ions I having an incidence angle less than the arrow ID with respect to the ion trap surface 511 were trapped on the side surface of the upper surface member of the ion trap space 51 that constitutes the plasma inflow hole 501. The simulation conditions for this example were set as follows: the pressure: 133 Pa; the temperature: 200° C.; and the flow rate of the processing gas flowing in from the plasma outflow hole 502: 4 sccm. The processing gas was hydrogen gas, and the mass fraction of hydrogen radicals in the plasma generation space 30 was 0.001%.
(Example 1) The diameter d3 of the ion trap space 51 was set to 10.4 mm. The height t3 of the ion trap space 51 was 0.2 mm.
(Example 2) The diameter d3 of the ion trap space 51 was set to 12 mm. The height t3 of the ion trap space 51 was 1 mm.
(Example 3) The diameter d3 of the ion trap space 51 was set to 16 mm. The height t3 of the ion trap space 51 was 3 mm.
(Example 4) The diameter d3 of the ion trap space 51 was set to 20 mm. The height t3 of the ion trap space 51 was 5 mm.

### B. Simulation Results

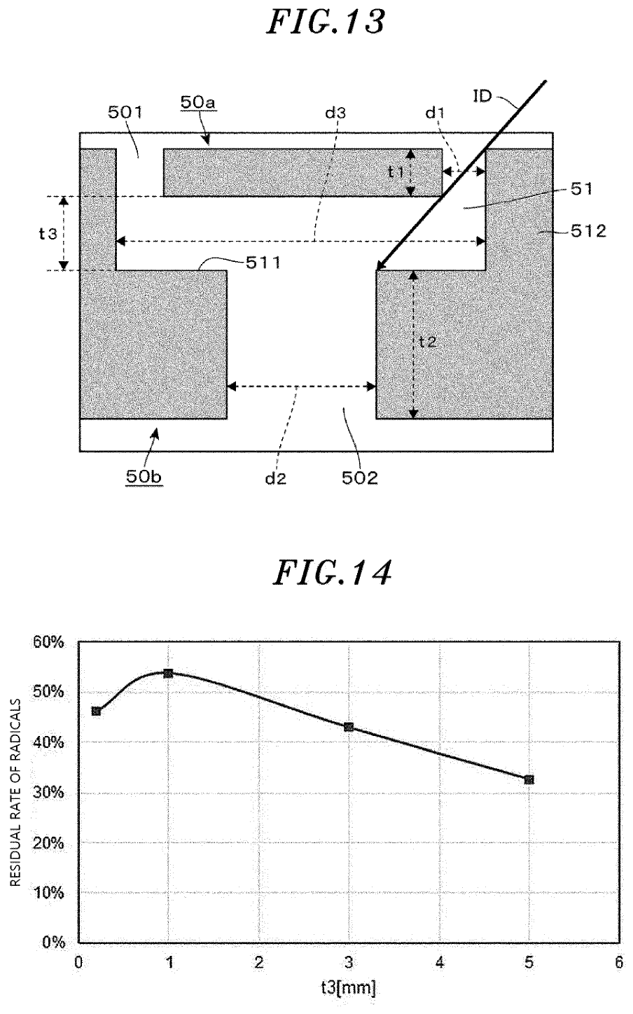

FIG. 14 is a plot of the residual rate of hydrogen radicals at the outlet position of the plasma outflow hole 502 with respect to the height t3 of the ion trap space 51 in each embodiment. As described above, in these embodiments, the design value of the diameter d3 is changed under the condition that the diameters d1 and d2 of the plasma inflow hole 501 and the plasma outflow hole 502 are fixed. The desired height t3 of the ion trap space 51 under the condition of each diameter d3 is derived based on the above-described method.

Referring to FIG. 14, when the diameter d3 of the ion trap space 51 is changed under the above-described conditions, the height t3 of the ion trap space 51 at which the residual rate of hydrogen radicals becomes maximum exists. For example, the preferred range of the height t3 of the ion trap space 51 at which the residual rate of radicals becomes 40% or more may be 0.1 mm or more and 3.1 mm or less. In the above range, the lower limit value (0.1 mm) of the height t3 of the ion trap space 51 is a processing constraint of the material.

1. An apparatus for performing plasma processing by supplying a processing gas in a plasma state to a substrate in a processing chamber, comprising:
a placing table provided in the processing chamber and configured to place the substrate thereon;
a plasma generation space located above the placing table and constituting a plasma generation mechanism configured to produce plasma from the processing gas;
a processing gas supply part configured to supply the processing gas to the plasma generation space; and
a shower plate located between the plasma generation space and the placing table, and forming a processing space for processing the substrate between the stage and the shower plate,
wherein the shower plate includes:
a first surface having a plurality of plasma inflow holes through which the plasma of the processing gas flows in from the plasma generation space;
a second surface having a plurality of plasma outflow holes through which the plasma of the processing gas flows out toward the processing space;
a plurality of ion trap spaces partitioned from each other by a partition wall provided between the first surface and the second surface, each of which has an ion trap surface for colliding with and trapping ions contained in the plasma of the processing gas flowing in from the plasma inflow holes, and then flowing the plasma out toward the processing space through the plasma outflow holes.

2. The apparatus of claim 1, wherein the ion trap surface is disposed at a position facing the outlet of the plasma inflow holes.

3. The apparatus of claim 1, wherein a height dimension of the ion trap space is within a range of 0.1 mm to 3.1 mm.

4. The apparatus of claim 1, wherein the ion trap space is formed in a cylindrical shape, and the cylindrical ion trap spaces are arranged in a matrix shape in the surface of the shower plate.

5. The apparatus of claim 1, wherein the ion trap space is formed in an annular shape along a circumferential direction of the shower plate, and the annular ion trap spaces are arranged concentrically in the surface of the shower plate.

6. The apparatus of claim 1, wherein the shower plate has a plurality of raw material gas supply holes for supplying a raw material gas that reacts with the processing gas in a plasma state to form a film on the substrate from the second surface toward the processing space, in addition to the plurality of plasma outflow holes.

7. The apparatus of claim 1, wherein the plasma generation space is formed between a conductive plate constituting the shower plate and having the first surface, and an electrode plate separated from the shower plate with the conductive plate interposed therebetween, and
the plasma generation mechanism includes a high-frequency power supply part connected to one of the electrode plate and the conductive plate, and a ground terminal connected to the other, and the processing gas supplied to the plasma generation space is converted into plasma by capacitive coupling between the electrode plate and the conductive plate.

8. The apparatus of claim 1, in which the opening area of the plasma outflow holes is smaller than the horizontal cross-sectional area of the ion trap space where the plasma outflow holes are formed.

9. The apparatus of claim 1, wherein the plasma outflow holes are formed such that the opening area gradually increases from the ion trap space side toward the processing space side.

10. The apparatus of claim 1, wherein the partition wall is provided with a conductive member to which a power is applied in order to electrically attract ions contained in the plasma of the processing gas flowing in from the plasma inflow holes and trap the ions on the wall surface.

11. The apparatus of claim 1, wherein the partition wall is provided with a communication passage for communicating the ion trap spaces adjacent to each other.

12. A method for performing plasma processing by supplying a processing gas in a plasma state to a substrate in a processing chamber,
wherein a placing table provided in the processing chamber and configured to place the substrate, a plasma generation space located above the placing table and constituting a plasma generation mechanism configured to convert the processing gas into plasma, a processing gas supply part configured to supply the processing gas to the plasma generation space, and a shower plate located between the plasma generation space and the placing table and forming a processing space for processing the substrate between the placing table and the plasma generation space are used,
the method comprising:
supplying the processing gas to the plasma generation space;
converting the processing gas supplied to the plasma generation space into plasma by the plasma generation mechanism;
causing the plasma of the processing gas generated by said converting the processing gas into plasma from the plasma generation space into a plurality of ion trap spaces formed in the shower plate through a plurality of plasma inflow holes formed in a first surface of the shower plate;
trapping ions by causing ions contained in the plasma of the processing gas flowing in from the plasma inflow holes to collide with ion trap surfaces in the plurality of ion trap spaces partitioned from each other by a partition wall; and
causing the plasma of the processing gas after the ions are trapped in said trapping ions to flow from the plurality of ion trap spaces into the process space through a plurality of plasma outflow holes formed in a second surface of the shower plate.
